(19) United States
(12) Patent Application Publication
(10) Pub. No.: US 2026/0031113 A1
(43) Pub. Date: Jan. 29, 2026

(54) MEMORY STORAGE DEVICE

(71) Applicant: Winbond Electronics Corp., Taichung City (TW)

(72) Inventor: Kai-Lin Chan, Hsinchu County (TW)

(73) Assignee: Winbond Electronics Corp., Taichung City (TW)

(21) Appl. No.: 18/984,954

(22) Filed: Dec. 17, 2024

(30) Foreign Application Priority Data
Jul. 26, 2024 (TW) 113127848

(51) Int. Cl. G11C 7/08; G11C 5/14

(52) U.S. Cl. CPC G11C 7/08; G11C 5/147

(57) ABSTRACT

Provided is a memory storage device including a memory cell array, a sensing amplifier device, and a controller circuit. The memory cell array includes a plurality of memory cells. The sensing amplifier device is coupled to at least one memory cell of the plurality of memory cells via a bit line and a complementary bit line. The sensing amplifier device detects differential pair signals on the bit line and the complementary bit line and outputs a detection result. The controller circuit is coupled to the sensing amplifier device. The controller circuit is configured to adjust a duration of a read period of the at least one memory cell according to the detection result.

### CROSS-REFERENCE TO RELATED APPLICATION

This application claims the priority benefit of Taiwan application serial no. 113127848, filed on Jul. 26, 2024. The entirety of the above-mentioned patent application is hereby incorporated by reference herein and made a part of this specification.

### BACKGROUND

### Technical Field

The disclosure relates to an electronic device, and in particular to a memory storage device.

### Description of Related Art

In the related art, for the application of memory storage device, when reading the data stored in the memory cell, the read duration setting is usually based on the time required to read the farthest memory cell, and the respective read durations for all memory cells are set to be the same. However, when reading a memory cell at a nearer location, it usually does not take as long to sense a sufficient voltage difference. Therefore, if the respective durations for all memory cells are set to the same length, unnecessary power consumption is wasted during subsequent precharge operations.

### SUMMARY

The disclosure provides a memory storage device, in which the duration of the read period of the memory cell can be adjusted to save power consumption.

An embodiment of the disclosure provides a memory storage device including a memory cell array, a sensing amplifier device, and a controller circuit. The memory cell array includes multiple memory cells. The sensing amplifier device is coupled to at least one memory cell among the multiple memory cells via a bit line and a complementary bit line. The sensing amplifier device is used to detect differential pair signals on the bit line and the complementary bit line and output a detection result. The controller circuit is coupled to the sensing amplifier device. The controller circuit is used to adjust the duration of the read period of at least one memory cell according to the detection result.

### BRIEF DESCRIPTION OF THE DRAWINGS

FIG. 1 is a schematic block diagram of a memory storage device according to an embodiment of the disclosure.

FIG. 2 is a schematic overview diagram of a sensing amplifier device according to the embodiment of FIG. 1.

FIG. 3 is a schematic diagram of signal waveforms during a reading operation in the embodiments of FIG. 1 and FIG. 2.

FIG. 4 is a schematic diagram of signal waveforms corresponding to FIG. 3 in the related art.

FIG. 5 is a schematic diagram of signal waveforms during a reading operation according to another embodiment of the disclosure.

### DESCRIPTION OF THE EMBODIMENTS

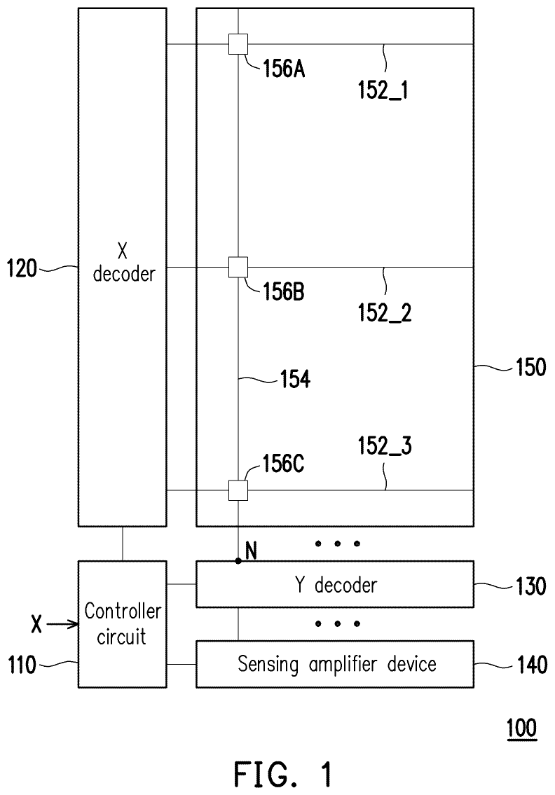

Refer to FIG. 1. A memory storage device 100 includes a controller circuit 110, an X decoder 120, a Y decoder 130, a sensing amplifier device 140, and a memory cell array 150. The controller circuit 110 is used to control the overall operation of the memory storage device 100, such as writing and reading operations on the memory cell according to an address signal X. For the circuit structures of the controller circuit 110, the X decoder 120, the Y decoder 130, and the memory cell array 150, reference may be made to common knowledge related to the technical field of the disclosure, and the disclosure does not limit the circuit structures of the devices mentioned above.

The memory cell array 150 includes multiple memory cells. FIG. 1 shows three memory cells 156A, 156B, and 156C, whose quantity and position are not used to limit the disclosure. The memory cells 156A, 156B, and 156C are connected to the X decoder 120 via word lines 152_1, 152_2, and 152_3 respectively. The memory cells 156A, 156B, and 156C are coupled to the Y decoder 130 via a bit line 154. The memory cells 156A, 156B, and 156C are coupled to the bit line set 154, in which a set of bit lines includes two complementary bit lines.

In this embodiment, the memory cell 156A (a first memory cell) is further away from the sensing amplifier device 140 than the memory cell 156B (a second memory cell), and the memory cell 156B is nearer to the sensing amplifier device 140 than the memory cell 156A. In the configuration, the memory cell 156A is located at the farthest position from the sensing amplifier device 140 on the bit line 154 (hereinafter referred to as the farthest position), the memory cell 156B is roughly at a middle position on the bit line 154, and the memory cell 156C is located at the position nearest to the sensing amplifier device 140 on the bit line 154 (hereinafter referred to as the nearest position). The memory cells 156A, 156B, and 156C may use n-bit binary codes to represent the addresses thereof. Since the memory cell 156A is at the farthest position, the memory cell 156B is at the middle position, and the memory cell 156C is at the nearest position, the n-th bit of the address signal X of the memory cell 156A may be encoded as 1, that is, X[n]=1, and the n-th bit of the address signal X of the memory cell 156B, 156C may be encoded as 0, that is, X[n]=0.

In addition, X[n] of other memory cells between the memory cells 156A, 156B may also be encoded as 1. X[n] of other memory cells between the memory cells 156B, 156C may also be encoded as 0.

In this embodiment, since the memory cell array 150 is roughly divided into two groups of memory cells located in the upper half and the lower half, the memory cell group located in the upper half of the memory cell array 150 has X[n]=1, and the memory cell group located in the lower half of the memory cell array 150 has X[n]=0. However, the disclosure is not limited thereto. In an embodiment, the memory cell may be divided into more groups with different distances from the sensing amplifier device 140 by using more most significant bits (MSBs) of the address signal X. For example, the most significant bit groups 11, 10, 01, and 00 may be used to correspond to memory cell groups from far to near the sensing amplifier device 140. Therefore, the controller circuit 110 may know the distance between the memory cell to be read and the sensing amplifier device 140 through the address signal X.

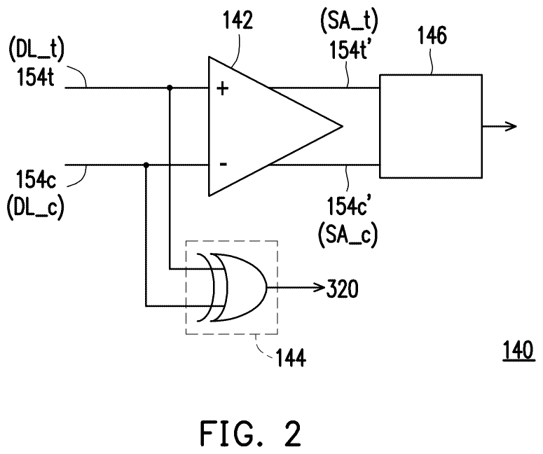

Referring to FIG. 2 to FIG. 4, the sensing amplifier device 140 is coupled to at least one memory cell via a bit line 154t and a complementary bit line 154c. The sensing amplifier device 140 is used to detect differential pair signals DL_t and DL_c on the bit line 154t and the complementary bit line 154c and output a detection result to the controller circuit 110.

Specifically, the sensing amplifier device 140 includes a sensing amplifier 142, a voltage detection circuit 144, and a digit logic circuit 146. The sensing amplifier 142 is coupled to at least one memory cell via the bit line 154t and the complementary bit line 154c. During a read period T1 or T2, the sensing amplifier 142 is used to receive the differential pair signals DL_t and DL_c on the bit line 154t and the complementary bit line 154c, so as to sense, amplify, and output the differential pair signals DL_t and DL_c read from the memory cell 156A or 156B. In the operation, the bit lines 154t, 154c are two complementary bit lines corresponding to the bit line set 154 in FIG. 1. Then, the digit logic circuit 146 determines a sensing result according to the output of the sensing amplifier 142, for example, determines whether the read value is bit 0 or bit 1. The circuit structures of the sensing amplifier 142 and the digit logic circuit 146 may be implemented with reference to common knowledge related to the technical field of the disclosure, and the disclosure does not limit the circuit structures of the sensing amplifier 142 and the digit logic circuit 146.

On the other hand, the voltage detection circuit 144 is coupled to at least one memory cell via the bit line 154t and the complementary bit line 154c. The voltage detection circuit 144 is used to detect the differential pair signals DL_t and DL_c and output a detection result 320 to the controller circuit 110. In this embodiment, the voltage detection circuit 144 may be used to detect whether the voltage level (DL_t or DL_c) of the bit line 154t or the complementary bit line 154c at a node N is less than a threshold value 330, so that the controller circuit 110 may adjust the duration of the read period T1 or T2 according to the detection result 320. In the operation, the node N is the node where the bit line 154 is connected to the Y decoder 130. In this embodiment, the voltage detection circuit 144 includes, for example, an XOR gate for determining the voltage levels of the differential pair signals DL_t and DL_c. The circuit structure of the voltage detection circuit 144 may also be implemented using other suitable digital circuits or analog circuits, and the disclosure is not limited thereto.

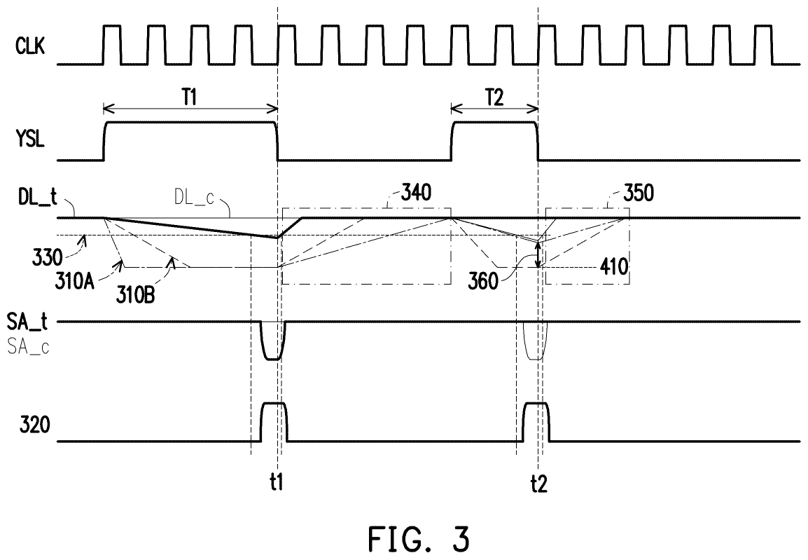

Further, refer to FIG. 3. A clock signal CLK is a reference signal when the memory storage device 100 performs a read operation. The pulse width of the high level of a selection signal YSL is the read periods T1, T2, in which the read period T1 is a read window for reading the memory cell 156A at the farthest position, and the read period T2 is a read window for reading the memory cell 156B at the middle position. The differential pair signals DL_t and DL_c are data swings of the bit line 154t and the complementary bit line 154c at the node N respectively. Voltage signals 310A, 310B are data swings of the bit line 154t at memory cells 156A, 156B respectively. Voltage signals SA_t and SA_c are data swings of the differential pair signal lines 154t′ and 154c′ at the output end of the sensing amplifier 142 respectively. The digit logic circuit 146 may determine whether the read value is bit 0 or bit 1 according to the voltage signals SA_t and SA_c. A signal 320 is the output signal (the detection result) of the voltage detection circuit 144.

In this embodiment, the controller circuit 110 is coupled to the sensing amplifier device 140. The controller circuit 110 may adjust the duration of the read period of at least one memory cell according to the detection result of the sensing amplifier device 140. Specifically, the controller circuit 110 may output the selection signal YSL according to the address signal X to determine the memory cell to be read and the duration of the read period, in which the address signal X includes location information of the memory cell to be read. Through the address signal X, the controller circuit 110 may know the distance of the memory cell to be read, and determine the read period. For example, according to the address signal X, the controller circuit 110 may know that the memory cell 156A at the farthest position is to be read now, and set the read period T1 as the duration shown in FIG. 3. In an embodiment, the duration of the read period T1 of the memory cell 156A may be a preset value.

Then, according to the address signal X, the controller circuit 110 may know that the memory cell 156B at the middle position is to be read now and may adjust the duration of the read period T2 according to the detection result 320 of the voltage detection circuit 144, and the duration of the read period T2 of the memory cell 156B is set to be shorter than the duration of the read period T1 of the memory cell 156A, as shown in FIG. 3.

Further, refer to FIG. 2 and FIG. 3. During the read period T1, the controller circuit 110 reads the memory cell 156A. At this time, the differential pair signal DL_t and the voltage signals 310A, 310B decrease from the initial voltage level over time. When the voltage detection circuit 144 detects that the differential pair signal DL_t is lower than the threshold value 330, the voltage detection circuit 144 outputs a high-level output signal 320 to terminate the read period T1. Then, the digit logic circuit 146 outputs the sensing data at a time t1. Afterward, a precharge operation 340 is performed by a precharge circuit (not shown) to return the differential pair signal DL_t and the voltage signals 310A, 310B to the initial voltage level.

Next, during the read period T2, the controller circuit 110 reads the memory cell 156B. At this time, the differential pair signal DL_c and the voltage signals 310A, 310B decrease from the initial voltage level over time. When the voltage detection circuit 144 detects that the differential pair signal DL_c is lower than the threshold value 330, the voltage detection circuit 144 outputs a high-level output signal 320 to terminate the read period T2. Then, the digit logic circuit 146 outputs the sensing data at a time t2. Afterward, a precharge operation 350 is performed by the precharge circuit to return the differential pair signal DL_c and the voltage signals 310A, 310B to the initial voltage level.

During the read period T2, the memory cell 156B is nearer to the sensing amplifier device 140 than the memory cell 156A, which means that the memory cell 156B has a smaller impedance. Therefore, the differential pair signal DL_c decreases faster than the differential pair signal DL_t. By utilizing this characteristic in the embodiment of the disclosure, the voltage detection circuit 144 is disposed in the sensing amplifier device 140 to detect the differential pair signal DL_c. The controller circuit 110 may adjust the duration of the read period T2 according to the detection result, so that the duration of the read period T2 is shorter than the duration of the read period T1.

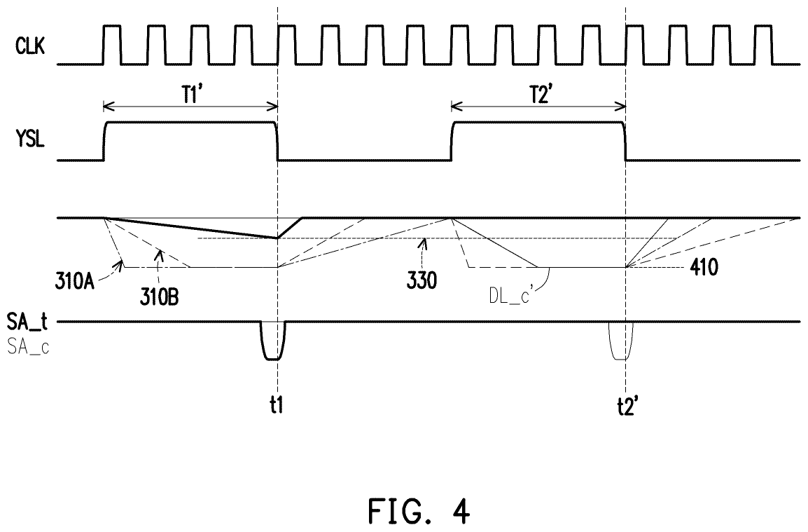

In the related art of FIG. 4, since the durations of read periods T1′ and T2′ are set to be equal and cannot be adjusted, at a time t2′, a differential pair signal DL_c′ decreases to a voltage level 410. As a result, in the related art, the power consumption of the precharge operation is increased. In contrast, in the embodiment of FIG. 3, the duration of the read period T2 is adjusted by detecting the differential pair signal DL_c, and the differential pair signal DL_c does not decrease to the voltage level 410. Therefore, when performing the precharge operation 350, at least the power consumption corresponding to a voltage swing 360 can be reduced.

In an embodiment, the voltage detection circuit 144 may also detect the voltage signal SA_t or SA_c and output the detection result to the controller circuit 110 to adjust the duration of the read period T1 or T2 accordingly.

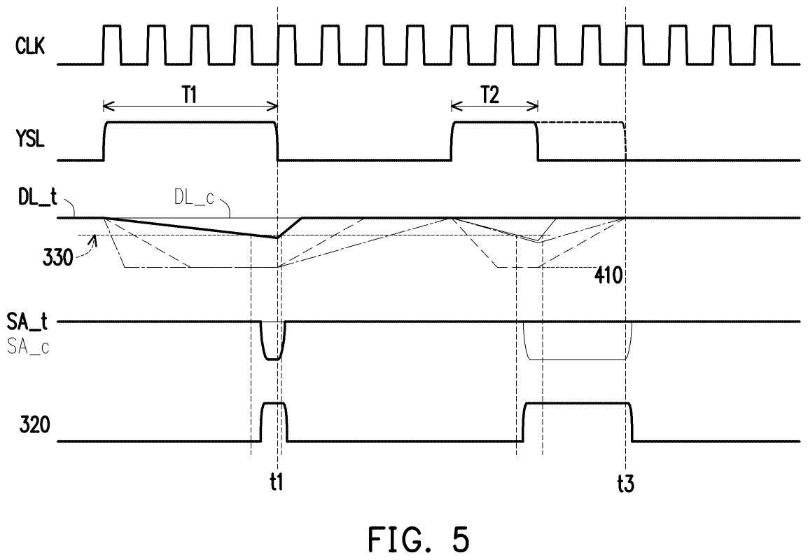

FIG. 5 is a schematic diagram of signal waveforms during a reading operation according to another embodiment of the disclosure. In this embodiment, during the read period T2, when the differential pair signal DL_c is lower than the threshold value 330, the voltage detection circuit 144 outputs a high-level output signal 320 with a longer duration to the controller circuit 110 to adjust the read period T2, so that the digit logic circuit 146 maintains to output sensing data at a time t3 when the read period T2 is adjusted.

In summary, in the embodiments of the disclosure, the sensing amplifier device is disposed with the voltage detection circuit, which may be used to detect the differential pair signal. The controller circuit 110 may adjust the duration of the read period of the near-end memory cell according to the detection result, so that the duration of the read period of the near-end memory cell may be shorter than the duration of the read period of the far-end memory cell, thereby the disclosure saves power consumption.

Although the disclosure has been disclosed above through embodiments, the embodiments are not intended to limit the disclosure. Persons with ordinary knowledge in the relevant technical field may make some modifications and changes without departing from the spirit and scope of the disclosure. Therefore, the protection scope of the disclosure shall be determined by the appended claims.

What is claimed is:

1. A memory storage device, comprising:
a memory cell array comprising a plurality of memory cells;
a sensing amplifier device coupled to at least one memory cell among the plurality of memory cells via a bit line and a complementary bit line, wherein the sensing amplifier device is configured to detect differential pair signals on the bit line and the complementary bit line and output a detection result; and
a controller circuit coupled to the sensing amplifier device and configured to adjust a duration of a read period of the at least one memory cell according to the detection result.

2. The memory storage device as claimed in claim 1, wherein the sensing amplifier device comprising:
a voltage detection circuit coupled to the at least one memory cell via the bit line and the complementary bit line, wherein the voltage detection circuit is configured to detect the differential pair signal and output the detection result.

3. The memory storage device as claimed in claim 2, wherein the voltage detection circuit comprises an XOR gate.

4. The memory storage device as claimed in claim 2, wherein the sensing amplifier device further comprises:
a sensing amplifier coupled to the at least one memory cell via the bit line and the complementary bit line and configured to sense, amplify, and output the differential pair signal; and
a digit logic circuit coupled to the sensing amplifier and configured to determine a sensing result according to an output of the sensing amplifier.

5. The memory storage device as claimed in claim 2, wherein in response to the voltage detection circuit detecting the differential pair signal being less than a threshold value, the voltage detection circuit outputs the detection result to the controller circuit.

6. The memory storage device as claimed in claim 1, wherein the plurality of memory cells comprise a first memory cell and a second memory cell, the first memory cell and the second memory cell are coupled to same bit line, and the controller circuit adjusts a duration of a read period of the second memory cell according to the detection result.

7. The memory storage device as claimed in claim 6, wherein a duration of a read period of the first memory cell is a preset value.

8. The memory storage device as claimed in claim 6, wherein the duration of the read period of the second memory cell is shorter than a duration of a read period of the first memory cell.

9. The memory storage device as claimed in claim 8, wherein the second memory cell is nearer to the sensing amplifier device than the first memory cell.

10. The memory storage device as claimed in claim 1, wherein the controller circuit is further configured to determine the duration of the read period of the at least one memory cell according to an address signal.
